(19) United States
(12) Patent Application Publication
(10) Pub. No.: US 2019/0039085 A1
(43) Pub. Date: Feb. 7, 2019

(54) CLOG-RESISTANT NOZZLE ASSEMBLY

(71) Applicant: ASM Technology Singapore Pte Ltd, Singapore (SG)

(72) Inventors: Kuok Hang MAK, Hong Kong (HK); Tsz Kit YU, Hong Kong (HK); Ping Kong CHOY, Hong Kong (HK); Gary Peter WIDDOWSON, Hong Kong (HK)

(21) Appl. No.: 15/670,163

(22) Filed: Aug. 7, 2017

(51) Int. Cl. B05B 15/02

(52) U.S. Cl. CPC B05B 15/02; H01L 21/6715

(57) ABSTRACT

A nozzle assembly having a nozzle body with nozzle bore extending between a proximal portion and a distal portion of the nozzle body; and a tube having a lumen extending between a proximal end and a distal end of the tube, wherein the tube is joined to the nozzle body through the nozzle bore, such that the proximal end of the tube extends beyond the proximal portion of the nozzle body and the distal end of the tube extends beyond the distal portion of the nozzle body.

### TECHNICAL FIELD

The present disclosure generally relates to a nozzle assembly. More particularly, the present disclosure describes various embodiments of a nozzle assembly, as well as a dispensing apparatus using the nozzle assembly.

### BACKGROUND

Nozzles are widely used in different industries when a dispensing process is required to dispense or deposit an amount of liquid from a container onto a surface. There is a variety of nozzles available for different dispensing applications and industries.

In the semiconductor industry, various dispensing processes are used to dispense liquid adhesives onto a lead frame for semiconductor device or die attachment. A liquid adhesive such as a particle-filled epoxy resin is commonly used. The rapid growth of the semiconductor industry has reduced the dimensions of semiconductor dies to micrometer and nanometer dimensions. The dispensing processes have become more demanding to achieve precise die attachment at such accuracies. A nozzle with a small internal diameter is often used in the dispensing processes to dispense small amounts of the particle-filled epoxy resin with excellent volume consistency and precision. However, the particles in the epoxy resin may cause blockages to occur at the nozzle. Moreover, with the continued reduction in semiconductor die sizes, the nozzle diameter will decrease and the ratio of the particle sizes to the nozzle diameter will increase, thereby increasing the likelihood of the particles causing blockages at the nozzle.

The occurrence of such blockages may be attributed to the internal geometry of the nozzle. Two possible modes of nozzle blockage have been identified. The first mode is the formation of a clogging bridge or arch. The clogging bridge usually forms near an intermediate inlet of the nozzle from one section to another. The second mode is the formation of air bubbles within the nozzle. The trapped air bubbles are likely to cause an airlock which blocks the dispensing pathway.

The formation of clogging bridges has been known to occur particularly in nozzles with a tapered bore. A clogging bridge is formed from particles in the liquid and is self-supported due to the normal and frictional forces developed from interactions between the particles belonging to or forming the clogging bridge itself. When the resultant force due to the normal and frictional forces is greater than the resultant force of the weight of the liquid and any external forces or loads applied on the particles, the clogging bridge develops and gradually becomes stabilized. The probability of clogging bridge formation is particularly related to the apex angle of the tapered bore. The structural strength and sturdiness of the clogging bridge are also related to the apex angle.

FIG. 1 illustrates a conventional nozzle 10 with a tapered bore 12. With a tapered or conical internal structure, the cross-section of the bore 12 changes along the dispensing pathway through which the liquid flows. Particularly, the cross-section is widest at the intermediate inlet 14 and narrowest at the outlet 16. As the particle-filled liquid enters the intermediate inlet 14 of the nozzle 10, the volume fraction increases and more particles are forced to flow through the intermediate inlet 14 at the same time. The volume fraction refers to the proportion of the volume occupied by the particles. The difference in fluid pressure along the tapered bore 12 may cause settlement of the particles near the intermediate inlet 14 where the fluid pressure is lower relative to the outlet 16. This facilitates formation of a clogging bridge near the intermediate inlet 14 and eventually leads to a higher chance of the nozzle 10 experiencing blockage.

Nozzles may also be blocked by trapped air in the liquid. In the nozzle 10 of FIG. 1, when the nozzle 10 is attached to a syringe, spaces or cavities at the intermediate inlet 14 and the outlet 16 should be filled with liquid. A purging process has to be performed to fill the cavities with the liquid before the syringe and nozzle 10 can be reliably used to dispense the liquid. During this purging process, air may remain in the cavities and be trapped as air bubbles in the liquid. The air bubbles may not be able to rise to the liquid surface to escape and are trapped within the liquid due to insufficient buoyancy forces to overcome the surface tension of the liquid. Furthermore, when liquid flows through the bore 12, the air bubbles are likely to travel into the dispensing pathway. An airlock may occur in the dispensing pathway, which would block or impede the liquid flow.

The dispensing performance of nozzles can worsen significantly due to the occurrence of nozzle blockage, particularly when a time-pressure dispenser is used with the nozzles. Control of the time and pressure parameters of such time-pressure dispensers may seek to improve the consistency of liquid dispensation. However, even if the parameters are well controlled, the dispensed liquid can still be inconsistent when the nozzle condition changes. Such time-pressure dispensers cannot ensure consistency of the liquid flow rate, when the nozzle has been affected by blockage. The aforementioned modes of nozzle blockage change the nozzle condition, and are likely to adversely affect effective control of the liquid flow.

Therefore, in order to address or alleviate at least one of the aforementioned problems and/or disadvantages, there is a need to provide a nozzle assembly in which at least one improvement and/or advantage over the aforementioned prior art is achieved.

### SUMMARY

According to a first aspect of the present disclosure, there is provided a nozzle assembly comprising: a nozzle body having a nozzle bore extending between a proximal portion and a distal portion of the nozzle body; and a tube having a lumen extending between a proximal end and a distal end of the tube, wherein the tube is joined to the nozzle body through the nozzle bore, such that the proximal end of the tube extends beyond the proximal portion of the nozzle body and the distal end of the tube extends beyond the distal portion of the nozzle body.

According to a second aspect of the present disclosure, there is a dispensing apparatus comprising a dispensing device and a nozzle assembly. The dispensing device comprises: a barrel portion for containing a liquid; and an outlet fluidly communicable with the barrel portion for dispensing the liquid. The nozzle assembly is coupled to the dispensing device via the outlet. The nozzle assembly comprises: a nozzle body having a nozzle bore; and a tube having a lumen extending between a proximal end and a distal end of the tube, the tube being joined to the nozzle body through the nozzle bore, wherein the proximal end of the tube extends beyond the nozzle body and through the outlet such that the proximal end of the tube is submersible in the liquid; and wherein the distal end extends beyond the nozzle body such that the liquid is configured to flow through the lumen and to be dispensable via the distal end.

An advantage of the present disclosure is that the nozzle assembly significantly mitigates the risks of a clogging bridge and/or an airlock forming along the dispensing pathway, thereby reducing the likelihood of nozzle blockages that prevent or impede liquid flow. Use of the nozzle assembly improves and stabilizes dispensing performance.

A nozzle assembly according to the present disclosure is thus disclosed herein. Various features, aspects, and advantages of the present disclosure will become more apparent from the following detailed description of the embodiments of the present disclosure, by way of non-limiting examples only, along with the accompanying drawings in accordance with embodiments of the present disclosure.

### BRIEF DESCRIPTION OF THE DRAWINGS

FIG. 1 illustrates a nozzle having a tapered bore according to prior art.

FIG. 2 illustrates a perspective view of a nozzle assembly in accordance with the preferred embodiment of the present disclosure.

FIG. 3 illustrates a cross-sectional view of the nozzle assembly in accordance with the preferred embodiment of the present disclosure.

FIG. 4 illustrates a perspective view of a dispensing apparatus including a dispensing device and the nozzle assembly in accordance with the preferred embodiment of the present disclosure.

FIG. 5 illustrates a cross-sectional view of the dispensing device and the nozzle assembly in accordance with the preferred embodiment of the present disclosure.

FIG. 6 illustrates a cross-sectional view of the dispensing device with the nozzle assembly coupled thereto in accordance with the preferred embodiment of the present disclosure.

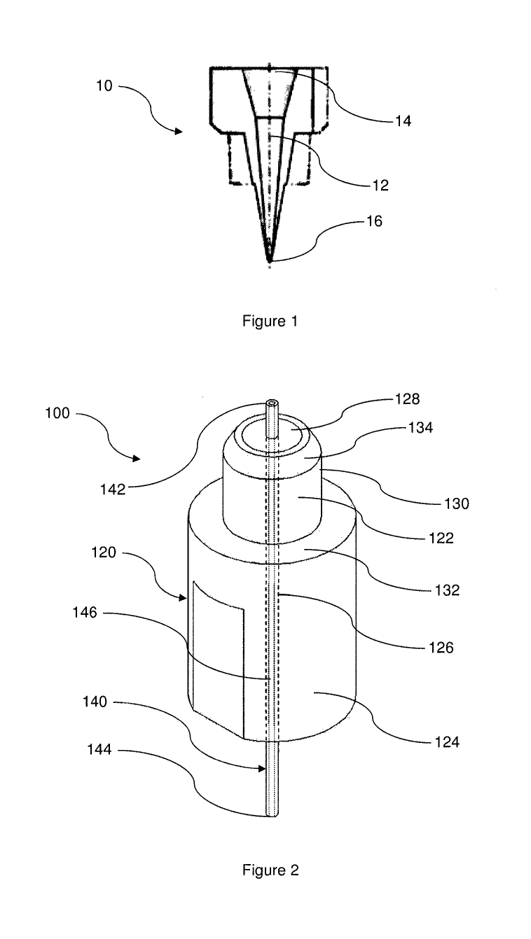

### DETAILED DESCRIPTION

For purposes of brevity and clarity, descriptions of embodiments of the present disclosure are directed to a nozzle assembly in accordance with the drawings. While aspects of the present disclosure will be described in conjunction with the embodiments provided herein, it will be understood that they are not intended to limit the present disclosure to these embodiments.

In various embodiments of the present disclosure, there is a nozzle assembly 100 as shown in FIG. 2. The nozzle assembly 100 includes a nozzle body or structure 120 and a tube 140 joined or connected to the nozzle body 120. Specifically, the tube 140 is joined to the nozzle body 120 integrally such that the nozzle body 120 and the tube 140 form a single unit or article. The nozzle body 120 includes a proximal portion or region 122 and a distal portion or region 124 integrally connected to each other. The nozzle body 120 further includes a bore or through-hole 126 extending between the proximal portion 122 and the distal portion 124. The tube 140 includes a proximal end 142, a distal end 144 opposing the proximal end 142, and a lumen 146 extending between the proximal end 142 and the distal end 144. The lumen 146 has a uniform cross-section such that the flow rate of a liquid through the lumen 146 is substantially constant. The tube 140 is joined to the nozzle body 120 through the bore 126, such that the proximal end 142 extends beyond or protrudes from the proximal portion 122 and the distal end 144 extends beyond or protrudes from the distal portion 124.

The tube 140 may be joined to the nozzle body 120 by inserting the tube 140 through the bore 126 and fixing the tube 140 to the nozzle body 120 permanently with an adhesive material. In one embodiment as shown in FIG. 2, the bore 126 has a uniform diameter identical to the outer diameter of the tube 140, such that the tube 140 adheres to the nozzle body 120 along the entire length of the bore 126. In another embodiment, the bore 126 has a non-uniform diameter, and the tube 140 adheres to the nozzle body 120 at the proximal portion 122 and distal portion 124 thereof. In yet another embodiment, the nozzle body 120 and tube 140 are integrally formed as a unitary article, such as by a moulding process.

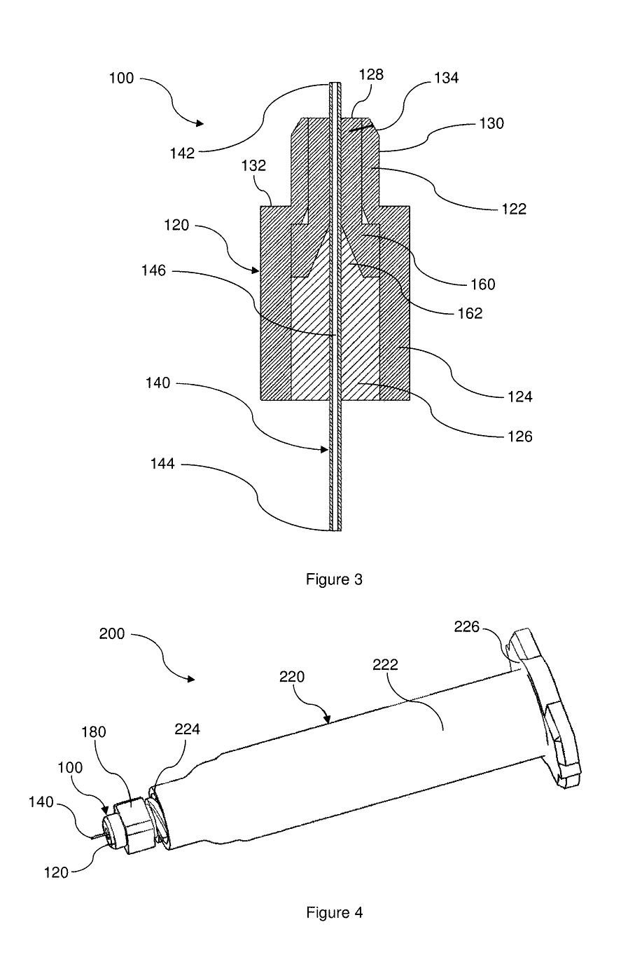

In some embodiments as shown in FIG. 3, the nozzle assembly 100 further includes a tube holder body 160 for supporting the tube 140 within the nozzle body 120. The tube holder body 160 includes a bore or through-hole 162 and the tube 140 is integrally joined to the tube holder body 160 though the bore 162. Particularly, the tube 140 is inserted into the tube holder body 160 through the bore 162 and fixed to the tube holder body 160 permanently with an adhesive material. The assembly of the tube holder body 160 and the tube 140 is integrally joined to the nozzle body 120 by inserting the tube holder body 160 through the bore 126 and joined to the nozzle body 120 permanently with an adhesive material.

In the nozzle assembly 100, the tube holder body 160 supports the tube 140 and aligns the position of the tube 140 within the nozzle body 120. Particularly, the tube holder body 160 aligns the tube 140 with respect to the nozzle body 120, such that the lumen 146 is concentric with respect to the bore 126 and the lumen 146 is perpendicular to a proximal surface 128 of the nozzle body 120.

The tube holder body 160 may be made of or coated with a material to attenuate forces and hoop stresses exerted on the tube 140, thereby mitigating the risk of structural damage to the tube 140. An example of this material is Teflon®, which has a Young's modulus that is comparatively much lower than that of the tube and this facilitates the insertion of the tube holder body 160 into the nozzle body 120 through the bore 126, and the insertion of the tube 140 into the tube holder body 160 through the bore 162. Other components of the nozzle assembly 100, including the nozzle body 120 and tube 140, may also be made of Teflon® or other materials known to the skilled person.

In various embodiments of the present disclosure, there is a dispensing apparatus 200 as shown in FIG. 4. The dispensing apparatus 200 includes a dispensing device 220 and the nozzle assembly 100 removably coupled or coupleable thereto. The dispensing device 220 is configured for dispensing a liquid, such as a particle-filled epoxy resin, contained in the dispensing device 220. For example, the dispensing device 220 may be a syringe and the tube 140 of the nozzle assembly 100 may be a needle for dispensing the liquid from the syringe.

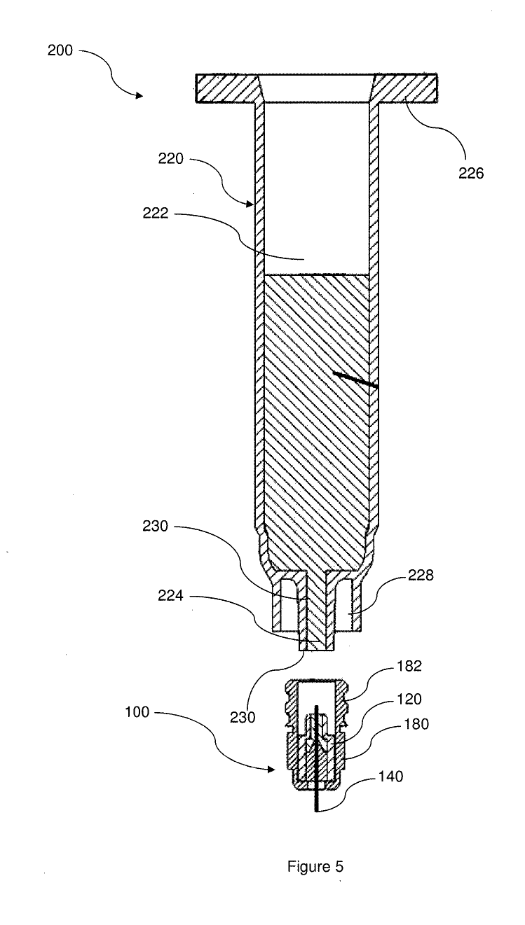

With further reference to FIG. 5, the dispensing device 220 includes a barrel portion or containment unit 222 for containing or holding the liquid. The dispensing device 220 further includes an outlet 224 fluidly communicable with the barrel portion 222 for dispensing the liquid. The dispensing device 220 further includes a plunger 226 actuable to dispense the liquid from the barrel portion 222 to the outlet 224. The outlet 224 includes a locking mechanism 228, such as a male portion of a Luer-Lok®. The nozzle assembly 100 further includes a nozzle holder body 180 coupled to the nozzle body 120. The nozzle holder body 180 includes a locking mechanism 182, such as a female portion of a Luer-Lok®, which is matingly engageable with the locking mechanism 228 of the outlet 224.

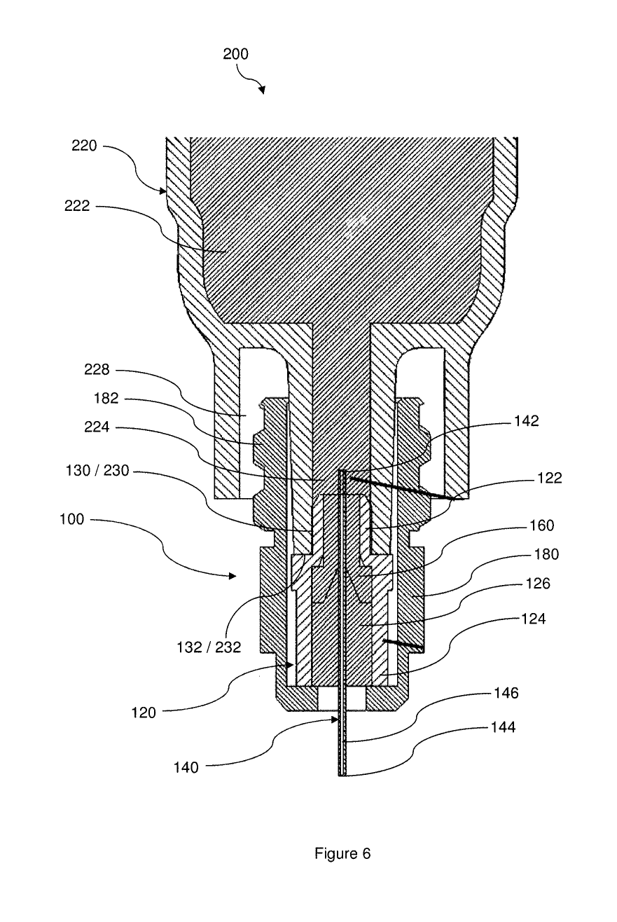

The nozzle assembly 100 is thus coupleable to the dispensing device 220 via the outlet 224. Upon coupling as shown in FIG. 6, the proximal portion 122 of the nozzle body 120 engages with the outlet 224 of the dispensing device 220. Through this engagement, at least one of a peripheral seal and a planar seal is formed between the nozzle body 120 and the outlet 224. The at least one of the peripheral seal and planar seal mitigates risk of leakage from the outlet 224 around the nozzle body 120.

In one embodiment, the proximal portion 122 engages with the outlet 224 through an interference fit. The proximal portion 122 has a slightly larger external dimension or outer diameter than an internal dimension or inner diameter of the outlet 224 to achieve the interference fit. The interference fit forms the peripheral seal between a peripheral mating surface 130 of the nozzle body 120 and a peripheral mating surface 230 of the outlet 224. Alternatively or additionally, the proximal portion 122 is narrower than the distal portion 124, such that a planar mating surface 132 is formed at the interface between the proximal portion 122 and the distal portion 124. The planar mating surface 132 is contactable against a planar mating surface 232 of the outlet 224. The engagement of the proximal portion 122 with the outlet 224 forms the planar seal between the planar mating surfaces 132 and 232.

The nozzle holder body 180 secures the coupling/engagement between the proximal portion 122 of the nozzle assembly 100 and the outlet 224 of the dispensing device 220 as a result of the locking engagement between the locking mechanisms 182 and 228. To facilitate the engagement of the proximal portion 122 to the outlet 224, the proximal portion 122 includes a chamfer or fillet 134 to guide the proximal portion 122 into the outlet 224. Actuation of the nozzle holder body 180 moves the proximal portion 122 towards the outlet 224 for engagement. The proximal portion 122 can be further forced into the outlet 224 by tightening the nozzle holder body 180, thereby tightening the locking engagement. The tightening of the nozzle holder body 180 results in the planar mating surface 132 exerting more pressure on the planar mating surface 232, thereby strengthening the planar seal.

In one embodiment of the dispensing apparatus 200 as shown in FIGS. 4 and 6, the dispensing device 220 is filled with a liquid for subsequent dispensation before the nozzle assembly 100 is coupled to the dispensing device 220. Particularly, the outlet 224 is filled with the liquid and the barrel portion 222 is at least partially filled with the liquid. Upon coupling, the proximal end 142 of the tube 140 extends into the outlet 224 such that the proximal end 142 is submerged in the liquid. It will be appreciated that the proximal end 142 of the tube 140 may be extended either partially into or entirely through the outlet 224.

In another embodiment, the nozzle assembly 100 may be coupled to the dispensing device 220 before the dispensing device 220 is filled with a liquid for subsequent dispensation. Upon coupling, the proximal end 142 of the tube 140 extends into the outlet 224 such that the proximal end 142 is submersible in the liquid. In other words, when the dispensing device 220 is filled with the liquid, the proximal end 142 will be submerged in the liquid.

As shown in FIG. 6, the liquid is fluidly communicable through the lumen 146 such that the liquid is dispensable from the dispensing device 220 via the distal end 144 of the nozzle assembly 100. For example, when the plunger 226 is actuated, the liquid flows from the proximal end 142 through the lumen 146 and is dispensed via the distal end 144. As the proximal end 142 is submerged and in direct contact with the liquid, no air cavity is formed around the proximal end 142. Thus, no purging process is required to fill an air cavity with the liquid. Conventionally, the purging process is a cause of air bubbles being trapped in the nozzle, particularly in one or more cavities thereof. Without the need for the purging process, air is not introduced into the nozzle assembly 100 and an airlock is unlikely to occur along the dispensing pathway.

The lumen 146 of the tube 140 forms part of the dispensing pathway for dispensation of the liquid, such as a particle-filled epoxy resin, contained in the dispensing device 220. The lumen 146 has a uniform cross-section such that the fluid pressure and volume fraction of the particle-filled epoxy resin remain substantially constant along the dispensing pathway. The uniform cross-section of the lumen 146 thus impedes formation of a clogging bridge or arch along the dispensing pathway. Moreover, the extension of the proximal end 142 into the liquid reduces the area where the clogging bridge may form, thereby weakening the structural integrity on which a clogging bridge may be founded.

Therefore, the nozzle assembly 100 addresses at least the aforementioned two modes of nozzle blockages that can occur separately or concurrently in a dispensing device 220. The nozzle assembly 100 significantly mitigates the risks of a clogging bridge and/or an airlock forming along the dispensing pathway, thereby reducing the chance of nozzle blockages that prevent or impede liquid flow, especially for particle-filled liquids such as a particle-filled epoxy resin. The liquid dispensation is more stable and consistent, and the flow rate of the dispensed liquid is substantially constant. Use of the nozzle assembly 100 in a dispensing apparatus 200 or together with a dispensing device 220 thus improves and stabilizes dispensing performance.

In the foregoing detailed description, the preferred embodiment of the present disclosure in relation to a nozzle assembly is described with reference to the provided figures. The description of the various embodiments herein is not intended to be limited only to specific or particular representations of the present disclosure, but merely to illustrate non-limiting examples of the present disclosure. The present disclosure serves to address at least one of the mentioned problems and issues associated with the prior art. Although only the preferred embodiment of the present disclosure is disclosed herein, it will be apparent to a person having ordinary skill in the art in view of this disclosure that a variety of changes and/or modifications can be made to the disclosed embodiments without departing from the scope of the present disclosure. Therefore, the scope of the present disclosure as well as the scope of the following claims is not limited to embodiments described herein.

1. A nozzle assembly coupleable to a dispensing apparatus for dispensing a liquid adhesive, the nozzle assembly comprising:
a nozzle body having a nozzle bore extending between a proximal portion and a distal portion of the nozzle body; and
a tube having a lumen extending between a proximal end and a distal end of the tube, the distal end of the tube having a flat tip with a uniform cross-section;
wherein the tube is joined to the nozzle body through the nozzle bore such that the proximal end of the tube extends beyond the proximal portion of the nozzle body and the distal end of the tube extends beyond the distal portion of the nozzle body for dispensing the liquid adhesive from the dispensing apparatus.

2. The nozzle assembly according to claim 1, wherein the lumen has a uniform cross-section along its length.

3. The nozzle assembly according to claim 1, wherein the nozzle bore and the lumen are concentric with respect to each other.

4. The nozzle assembly according to claim 1, further comprising a tube holder body within the nozzle body for supporting the tube, wherein the tube holder body is joined to the nozzle body through the nozzle bore.

5. The nozzle assembly according to claim 4, wherein the tube holder body further comprises a tube holder bore, and the tube is joined to the tube holder bore of the tube holder body.

6. (canceled)

7. The nozzle assembly according to claim 6, further comprising a nozzle holder body for coupling between the nozzle assembly to the dispensing device.

8. The nozzle assembly according to claim 6, wherein the proximal portion of the nozzle body is inserted into an outlet of the dispensing device upon coupling.

9. The nozzle assembly according to claim 8, wherein the proximal end of the tube extends into the outlet such that the proximal end is submerged in the liquid adhesive upon coupling.

10. The nozzle assembly according to claim 9, wherein the liquid adhesive is configured to flow through the lumen, such that the liquid adhesive is dispensable from the dispensing device via the distal end of the tube.

11. The nozzle assembly according to claim 8, wherein at least one of a peripheral seal and a planar seal is formed between the nozzle body and the outlet.

12. The nozzle assembly according to claim 11, wherein the proximal portion of the nozzle body engages with the outlet through an interference fit such that the interference fit forms the peripheral seal.

13. The nozzle assembly according to claim 11, wherein the proximal portion is narrower than the distal portion of the nozzle body such that the engagement of the proximal portion with the outlet forms the planar seal.

14. The nozzle assembly according to claim 8, wherein the proximal portion of the nozzle body comprises a chamfer for facilitating engagement of the nozzle body with the outlet.

15. A dispensing apparatus for dispensing a liquid adhesive, comprising:
a dispensing device comprising:
a barrel portion for containing a liquid adhesive; and
an outlet fluidly communicable with the barrel portion for dispensing the liquid adhesive; and
a nozzle assembly coupled to the dispensing device via the outlet, the nozzle assembly comprising:
a nozzle body having a nozzle bore; and
a tube having a lumen extending between a proximal end and a distal end of the tube, the tube being joined to the nozzle body through the nozzle bore and the distal end of the tube having a flat tip with a uniform cross-section,
wherein the proximal end of the tube extends beyond the nozzle body and through the outlet such that the proximal end of the tube is submersible in the liquid adhesive; and
wherein the distal end extends beyond the nozzle body such that the liquid adhesive is configured to flow through the lumen and to be dispensable via the distal end.

16. The dispensing apparatus according to claim 15, the nozzle assembly further comprising a tube holder body for supporting the tube within the nozzle body, wherein the tube holder body is joined to the nozzle body through the nozzle bore.

17. The dispensing apparatus according to claim 15, further comprising a nozzle holder body for coupling the nozzle assembly to the dispensing device.

18. The dispensing apparatus according to claim 15, wherein the proximal portion is engaged with the outlet such that at least one of a peripheral seal and a planar seal is formed between the nozzle body and the outlet.

19. The dispensing apparatus according to claim 18, wherein the proximal portion is engaged with the outlet through an interference fit such that the interference fit forms the peripheral seal.

20. The dispensing apparatus according to claim 18, wherein the proximal portion is narrower than the distal portion such that the engagement of the proximal portion with the outlet forms the planar seal.
